(19) United States
(12) Patent Application Publication
(10) Pub. No.: US 2026/0173505 A1
(43) Pub. Date: Jun. 18, 2026

(54) SEMICONDUCTOR DEVICE HAVING DIODE STRUCTURES ELECTRICALLY CONNECTED TO PADS

(71) Applicant: SK hynix Inc., Gyeonggi-do (KR)

(72) Inventor: Tae Beom KIM, Gyeonggi-do (KR)

(21) Appl. No.: 19/218,622

(22) Filed: May 27, 2025

(30) Foreign Application Priority Data
Dec. 17, 2024 (KR) 10-2024-0188132

(51) Int. Cl. H10D 84/82; H01L 21/66; H10D 12/00; H10D 62/10; H10D 62/60

(52) U.S. Cl. CPC H10D 84/82; H10D 12/211; H10D 62/116; H10D 62/124; H10D 62/60; H10P 74/273

(57) ABSTRACT

A semiconductor device including a first I/O diode having a first I/O first electrode electrically connected to a first voltage node and a first I/O second electrode electrically connected to a first pad; a second I/O diode having a second I/O first electrode electrically connected to the first pad and a second I/O second electrode electrically connected to a second voltage node; a first core diode having a first core diode first electrode electrically connected to the first voltage node and a first core diode second electrode electrically connected to a second pad; and a second core diode having a second core diode first electrode electrically connected to the second pad and a second core diode second electrode electrically connected to the second voltage node is described.

### CROSS-REFERENCE TO RELATED APPLICATIONS

This patent document claims priority under 35 U.S.C. 119(a) to Korean Patent Application No. 10-2024-0188132, filed on Dec. 17, 2024, which is incorporated herein by reference in its entirety.

### TECHNICAL FIELD

Embodiments of the present disclosure relate to a semiconductor device having diode structures.

### BACKGROUND

Semiconductor devices are known to include I/O (input/output) elements and core elements. The specifications of the I/O elements and core elements may be different from each other. In these instances, appropriate structures and methods of properly testing the I/O elements and core elements are demanded.

### SUMMARY

Embodiments of the present disclosure provide circuits, structures, and methods being configured to independently measure characteristics of I/O elements and core elements, respectively.

In accordance with an embodiment of the present disclosure, a semiconductor device includes a first I/O (input/output) diode having a first I/O first electrode electrically connected to a first voltage node and a first I/O second electrode electrically connected to a first pad; a second I/O diode having a second I/O first electrode electrically connected to the first pad and a second I/O second electrode electrically connected to a second voltage node; a first core diode having a first core diode first electrode electrically connected to the first voltage node and a first core diode second electrode electrically connected to a second pad; and a second core diode having a second core diode first electrode electrically connected to the second pad and a second core diode second electrode electrically connected to the second voltage node. An ion doping concentration of the first I/O first electrode is higher than an ion doping concentration of the second core diode first electrode. An ion doping concentration of the first I/O second electrode is higher than an ion doping concentration of the second core diode second electrode.

In accordance with an embodiment of the present disclosure, a semiconductor device includes a first diode structure electrically connected to a first pad; and a second diode structure electrically connected to a second pad. The first diode structure includes a plurality of first fin structures; first well regions disposed in lower regions of the plurality of first fin structures; and first N-doped regions and second P-doped regions disposed in upper regions of the plurality of first fin structures. The second diode structure includes a plurality of second fin structures; second well regions disposed in lower regions of the plurality of second fin structures; and second N-doped regions and second P-doped regions disposed in upper regions of the plurality of second fin structures. A number of the plurality of first fin structures is greater than a number of the plurality of second fin structures.

In accordance with an embodiment of the present disclosure, semiconductor device includes a first I/O (input/output) diode having a first I/O first electrode electrically connected to a power voltage node and a first I/O second electrode electrically connected to an I/O pad; a second I/O diode having a second I/O first electrode electrically connected to the I/O pad and a second I/O second electrode electrically connected to a ground voltage node; a first core diode having a first core diode first electrode electrically connected to the power voltage node and a first core diode second electrode electrically connected to a core pad; and a second core diode having a second core diode first electrode electrically connected to the core pad and a second core diode second electrode electrically connected to the ground voltage node. A doping concentration of each of doping regions of the first and second I/O diodes is higher than a doping concentration of each of doping regions of the first and second core diodes. A volume of each of the doping regions of the first and second I/O diodes is greater than a volume of each of the doping regions of the first and second core diodes.

These and other features and advantages of the embodiments of the present disclosure will become apparent to those skilled in the art from the following detailed description in conjunction with the following drawings.

### BRIEF DESCRIPTION OF THE DRAWINGS

FIGS. 1A and 1B are top views illustrating arrangements of connection pads of semiconductor devices according to embodiments of the present disclosure.

FIG. 2 is a schematic view illustrating test circuits according to embodiments of the present disclosure.

FIG. 3A is a view schematically illustrating an I/O element test circuit according to an embodiment of the present disclosure, and FIG. 3B is a view schematically illustrating a core element test circuit according to an embodiment of the present disclosure.

FIG. 4A is a view schematically illustrating an I/O element test structure according to an embodiment of the present disclosure, and FIG. 4B is a view schematically illustrating a core element test structure according to an embodiment of the present disclosure.

FIG. 5A is a view schematically illustrating an I/O element test structure according to an embodiment of the present disclosure, and FIG. 5B is a view schematically illustrating a core element test structure according to an embodiment of the present disclosure.

### DETAILED DESCRIPTION

Embodiments of the present disclosure are described in detail with reference to the accompanying drawings. Specific structural or functional descriptions of specific embodiments are provided as examples to describe the technical concepts that are disclosed in the present application. However, it should be understood that various other examples or embodiments in accordance with the technical concepts of the present disclosure may be carried out in various forms by those with ordinary skill in the art without departing from the scope of the present disclosure. Hence, the present invention is not limited only to the described examples or embodiments.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the descriptions herein. All embodiments within the meaning and range of equivalency of the claims are included within their scope.

Throughout the specification and claims, the “I/O” means “input and output (Input/output)”.

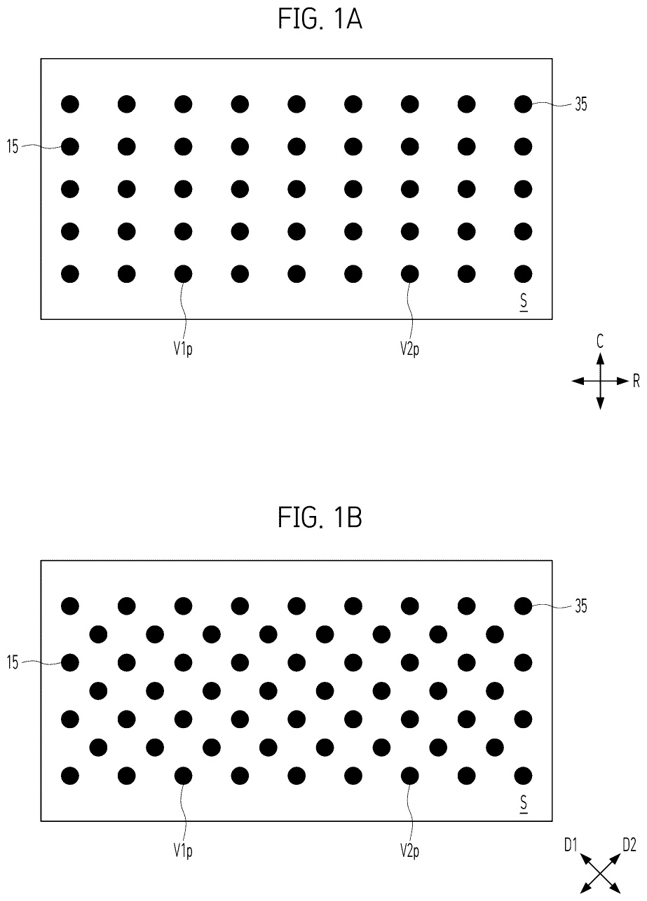

FIGS. 1A and 1B are top views illustrating arrangements of connection pads 15, 35, V1p, and V2p of semiconductor devices according to embodiments of the present disclosure. Although only four connection pads 15, 35, V1p, and V2p are labeled, any of the remaining connection pads may be connection pads 15, connection pads 35, first power pads V1p, or second power pads V2p as shall be described in detail further below herein. Referring to FIGS. 1A and 1B, the connection pads 15, 35, V1p, and V2p of each of the semiconductor devices may be arranged in a matrix form over a surface S of each of the semiconductor devices. For example, referring to FIG. 1A, the connection pads 15, 35, V1p, and V2p may be arranged in a matrix form aligned in a first direction R and a second direction C over the surface S of the semiconductor device. The first direction R and the second direction C may be perpendicular to each other. Referring to FIG. 1B, the connection pads 15, 35, V1p, and V2p may be arranged in a matrix form aligned in a first diagonal direction D1 and a second diagonal direction D2 over the surface S of the semiconductor device. The first diagonal direction D1 and the second diagonal direction D2 may be perpendicular to each other. In an embodiment, the connection pads 15, 35, V1p, and V2p may be randomly arranged in an entirety or partially (for example, only a portion being arranged randomly).

The connection pads 15, 35, V1p, and V2p may include an I/O element connection pad 15, a core element connection pad 35, a first power pad V1p, and a second power pad V2p. In an embodiment, the I/O element connection pad 15 may be disposed closer to at least one of four sides of the surface S than to a center of the surface S. The core element connection pad 35, the first power pad V1p, and the second power pad V2p may be disposed at arbitrary or random positions.

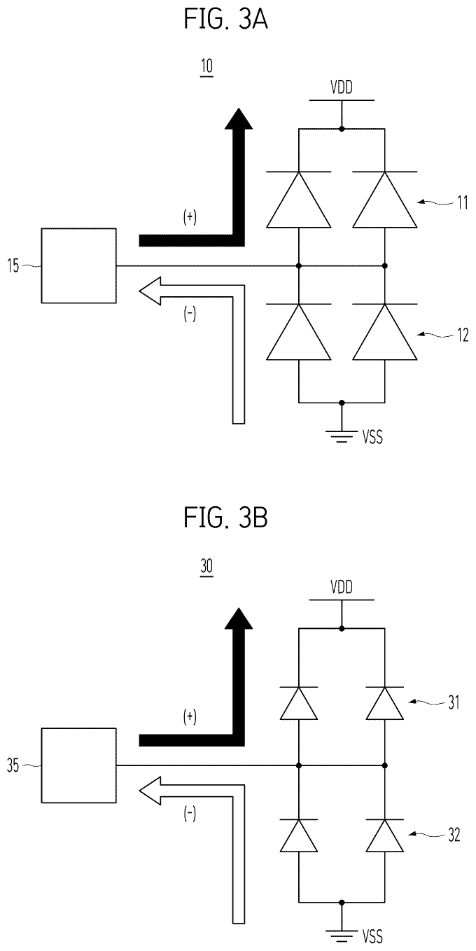

The I/O element connection pad 15 may be electrically connected to a signal I/O circuit, and may transmit electrical signals such as a command signal, a clock signal, a strobe signal, an address signal, and a data signal. The I/O element connection pad 15 may be used for a signal I/O element test for measuring characteristics of a signal I/O circuit. For example, the I/O element connection pad 15 may be electrically connected to the I/O element test circuit 10 (See, herein below, the description with respect to FIG. 3A).

The core element connection pad 35 may be connected to a core element test circuit 30 (See, herein below, the description with respect to FIG. 3B) for measuring characteristics of a core element circuit. The core element circuit may include transistors and interconnections that perform signal processing and calculation.

The first power pad V1p may be used to provide transfer a first power, e.g., a power voltage VDD, and the second power pad V2p may be used to provide a second power, e.g., a ground voltage VSS.

The I/O element test circuit 10 and the core element test circuit 30 may be implemented together as described herein below to enable testing the I/O elements and core elements.

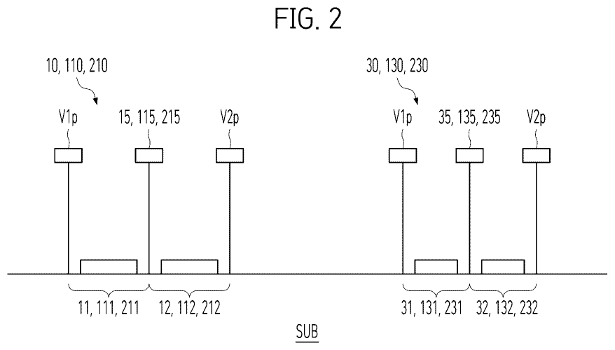

FIG. 2 is a schematic view illustrating test circuits 10, 30, 110, 130, 210, and 230 according to embodiments of the present disclosure. Referring to FIG. 2, the test circuits 10, 30, 110, 130, 210, and 230 may include connection pads 15, 35, 115, 135, 215, and 235, first diode structures 10, 110, and 130, and second diode structures 30, 130, and 230.

FIG. 3A is a view schematically illustrating an I/O element test circuit 10 according to an embodiment of the present disclosure, and FIG. 3B is a view schematically illustrating a core element test circuit 30 according to an embodiment of the present disclosure. The I/O element test circuit 10 of FIG. 3A may be disposed in an I/O element region in the semiconductor device. The core element test circuit 30 of FIG. 3B may be disposed in a core element region in the semiconductor device. The I/O element test circuit 10 of FIG. 3A and the core element test circuit 30 of FIG. 3B may be implemented in a same device, such as with respect to FIGS. 1A and 1B, to enable testing of I/O elements and core elements.

Referring to FIG. 3A, the I/O element test circuit 10 may include a first I/O diode 11, a second I/O diode 12, and an I/O element connection pad 15. An N-type electrode (cathode electrode) of the first I/O diode 11 may be electrically connected to a first voltage node VDD, for example, a power supply node. The first voltage node VDD may be electrically connected to the first power pad V1p. A P-type electrode (anode electrode) of the second I/O diode 12 may be electrically connected to a second voltage node VSS, for example, a ground node. The second voltage node VSS may be electrically connected to the second power pad V2p. The P-type electrode of the first I/O diode 11, the N-type electrode of the second I/O diode 12, and the I/O element connection pad 15 may be electrically connected to each other. Each of the first I/O diode 11 and the second I/O diode 12 may include a plurality of unit I/O diodes connected in parallel with each other. In the illustrated example of FIG. 3A, each of the first I/O diode 11 and the second I/O diode 12 may include two unit I/O diodes connected in parallel with each other.

When a positive (+) current is applied to the I/O element connection pad 15, the positive (+) current may flow through the first I/O diode 11 to the first voltage node VDD (illustrated in FIGS. 3A and 3B by a black arrow (+)). Since the positive (+) current does not pass through the second I/O diode 12, a current may not flow through the second voltage node VSS.

When a negative (−) current is applied to the I/O element connection pad 15, the negative (−) current may not pass through the first I/O diode 11, and thus a current may not flow to the first voltage node VDD. The negative (−) current may pass through the second I/O diode 12 and flow to the second voltage node VSS. That is, a current may flow from the first voltage node VSS to the I/O element connection pad 15. (illustrated in FIGS. 3A and 3B by a white arrow (−)).

A current value flowing from the I/O element connection pad 15 to the first voltage node VDD and a current value flowing from the second voltage node VSS to the I/O element connection pad 15 may be measured according to a current value applied to the I/O element connection pad 15. According to the measured current value, characteristics of the first and second I/O diodes 11 and 12 can be measured. For example, resistors and threshold voltages of the first and second I/O diodes 11 and 12 can be calculated. Based on this, the characteristics of I/O elements, for example, I/O transistors, can be measured.

Referring to FIG. 3B, the core element test circuit 30 may include a first core diode 31, a second core diode 32, and a core element connection pad 35. An N-type electrode of the first core diode 31 may be electrically connected to a first voltage node VDD. The first voltage node VDD may be electrically connected to the first power pad V1p. A P-type electrode of the second core diode 32 may be electrically connected to a second voltage node VSS. The second voltage node VSS may be electrically connected to the second power pad V2p. The P-type electrode of the first core diode 31, the N-type electrode of the second core diode 32, and the core element connection pad 35 may be electrically connected to each other. Each of the first core diode 31 and the second core diode 32 may include a plurality of unit core diodes connected in parallel with each other. In the illustrated example of FIG. 3B, each of the first core diode 31 and the second core diode 32 may include two unit core diodes connected in parallel with each other.

When a positive (+) current is applied to the core element connection pad 35, the positive (+) current may flow through the first core diode 31 to the first voltage node VDD. (See the black arrow (+)). The positive (+) current may not pass through the second core diode 32, and thus a current may not flow through the second voltage node VSS.

When a negative (−) current is applied to the core element connection pad 35, the negative (−) current may not pass through the first core diode 31, and thus a current may not flow to the first voltage node VDD. The negative (−) current may pass through the second core diode 32 and flow to the second voltage node VSS. That is, a current may flow from the second voltage node VSS to the core pad 35. (See the white arrow (−)).

A current value flowing from the core element connection pad 35 to the first voltage node VDD and a current value flowing from the second voltage node VSS to the core element connection pad 35 may be measured according to a current value applied to the core element connection pad 35. Threshold voltages of the first and second core diodes 31 and 32 can be calculated according to the measured current value. Based on this, characteristics of core elements, for example, core transistors, can be measured.

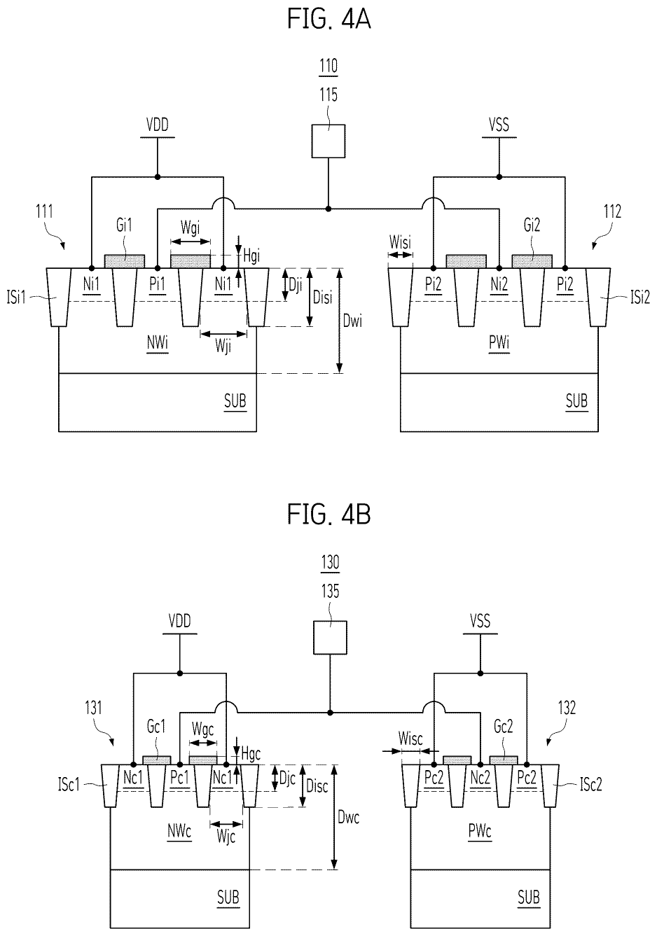

FIG. 4A is a view schematically illustrating an I/O element test structure 110 according to an embodiment of the present disclosure, and FIG. 4B is a view schematically illustrating a core element test structure 130 according to an embodiment of the present disclosure. The I/O element test structure 110 of FIG. 4A and the core element test structure 130 of FIG. 4B may correspond to the I/O element test circuit 10 of FIG. 3A and the core element test circuit 30 of FIG. 3B, respectively.

Referring to FIG. 4A, the I/O element test structure 110 may include a first I/O diode structure 111, a second I/O diode structure 112, and an I/O element connection pad 115. Similar to the I/O element connection pad 15 of FIGS. 1A and 1B, the I/O element connection pad 115 may be exposed over a surface S of a semiconductor device. The I/O element connection pad 115 may be one of uppermost metal layers of the semiconductor device. In one embodiment, the I/O element connection pad 115 may be a bump pad or a bump.

The first I/O diode structure 111 may include an I/O N-well region NWi, first I/O N-doped regions Ni1, and a first I/O P-doped region Pi1 in a substrate SUB. The first I/O N-doped regions Ni1 and the first I/O P-doped region Pi1 may be disposed to be defined and separated apart from each other by first I/O isolation regions ISi1. The first I/O P-doped region Pi1 may be disposed between the first I/O N-doped regions Ni1. The first I/O N-doped regions Ni1 may correspond to the N-type electrode of FIG. 3A and the first I/O P-doped region Pi1 may correspond to the P-type electrode of FIG. 3A.

The first I/O diode structure 111 may further include first I/O gate electrodes Gi1 disposed over some of the first I/O isolation regions ISi1. The first I/O isolation regions ISi1 may be shallow trench isolation (STI) regions. The first I/O gate electrodes Gi1 may include a gate electrode structure. For example, each of the first I/O gate electrodes Gi1 may include a gate insulating layer, a gate electrode, and a gate capping layer. The first I/O gate electrodes Gi1 may be dummy gate electrodes. For example, electrical bias may not be applied to the first I/O gate electrodes Gi1, and the first I/O gate electrodes Gi1 may be electrically floated. In one embodiment, the first I/O gate electrodes Gi1 may vertically and partially overlap the first I/O N-doped regions Ni1 and/or the first I/O P-doped region Pi1.

The substrate SUB may include a semiconducting layer such as a silicon layer. The I/O N-well region NWi may include N-type ions doped with an I/O N-well concentration in the substrate SUB. For example, the I/O N-well region NWi may be a silicon layer including at least one of arsenic (As), phosphorus (P), or antimony (Sb). The first I/O N-doped regions Ni1 may include N-type ions doped with a first I/O N-doping concentration in the I/O N-well region NWi of the substrate SUB. For example, the first I/O N-doped regions Ni1 may be a silicon layer including at least one of arsenic (As), phosphorus (P), or antimony (Sb). The first I/O P-doped region Pi1 may include P-type ions doped with a first I/O P-doping concentration in the I/O N-well region NWi of the substrate SUB. For example, the first I/O P-doped region Pi1 may be a silicon layer including at least one of boron (B) and boron fluoride (BF2). The I/O N-well concentration may be the same as or similar to the first I/O N-doping concentration. In one embodiment, the first I/O N-doping concentration may be higher than the I/O N-well concentration. The first I/O P-doping concentration may be lower than the first I/O N-doping concentration. The first I/O P-doping concentration may be lower than the I/O N-well concentration. Both of the first I/O N-doped regions Ni1 may be commonly electrically connected to the first voltage node VDD. The first voltage node VDD may be electrically connected to the first power pad V1p. The first I/O P-doped region Pi1 may be electrically connected to the I/O element connection pad 115.

The second I/O diode structure 112 may include an I/O P-well region PWi, second I/O P-doped regions Pi2, and a second I/O N-doped region Ni2 in the substrate SUB. The second I/O P-doped regions Pi2 and the second I/O N-doped region Ni2 may be disposed to be separated apart from each other by second I/O isolation regions ISi2. The second I/O N-doped region Ni2 may be disposed between the second I/O P-doped regions Pi2. The second I/O diode structure 112 may further include second I/O gate electrodes Gi2 disposed over some of the second I/O isolation regions ISi2. The second I/O gate electrodes Gi2 may include a gate electrode structure. For example, each of the second I/O gate electrodes Gi2 may include a gate insulating layer, a gate electrode, and a gate capping layer. The second I/O gate electrodes Gi2 may be dummy gate electrodes. For example, electrical bias may not be applied to the second I/O gate electrodes Gi2, and the second I/O gate electrodes Gi2 may be electrically floated. In one embodiment, the second I/O gate electrodes Gi2 may vertically and partially overlap the second I/O P-doped regions Pi2 and/or the second I/O N-doped region Ni2.

The I/O P-well region PWi may include P-type ions doped at an I/O P-well concentration in the substrate SUB. For example, the I/O P-well region PWi may be a silicon layer including at least one of boron (B) or boron fluoride (BF2). The second I/O P-doped regions Pi2 may include P-type ions doped with a second I/O P-doping concentration in the I/O P-well region PWi of the substrate SUB. For example, the second I/O P-doped regions Pi2 may be silicon layers including at least one of boron (B) and boron fluoride (BF2). The second I/O N-doped region Ni2 may include N-type ions doped in the I/O P-well region PWi of the substrate SUB. For example, the second I/O N-doped region Ni2 may be a silicon layer including at least one of arsenic (As), phosphorous (P), or antimony (Sb). The second I/O N-doped region Ni2 may include N-type ions doped with a second I/O N-doping concentration. The I/O P-well concentration may be the same as or similar to the second I/O P-doping concentration. In one embodiment, the second I/O P-doping concentration may be higher than the I/O P-well concentration. The second I/O N-doping concentration may be lower than the second I/O P-doping concentration. The second I/O N-doping concentration may be lower than the I/O N-well concentration. Both the second I/O P-doped regions Pi2 may be commonly and electrically connected to the second voltage node VSS. The second voltage node VSS may be electrically connected to the second power pad V2p. The second I/O N-doped region Ni2 may be electrically connected to the I/O element connection pad 115. The first I/O P-doped region Pi1 and the second I/O N-doped region Ni2 may be electrically connected to each other.

Specifications of the first and second I/O diode structures 111 and 112 may be the same as specifications of I/O transistors disposed in the I/O region of the semiconductor device. For example, the specifications of well regions, source regions, and drain regions of the first and second I/O diode structures 111 and 112 and the I/O transistors may be the same to each other, respectively. Thus, electrical characteristics of the I/O transistors may be measured by using the first and second I/O diode structures 111 and 112.

Referring to FIG. 4B, the core element test structure 130 may include a first core diode structure 131, a second core diode structure 132, and a core element connection pad 135. Similar to the core element connection pad 35 of FIGS. 1A and 1B, the core element connection pad 135 may be exposed on the surface S of the semiconductor device. The core element connection pad 135 may be one of uppermost metal layers of the semiconductor device. For example, the core element connection pad 135 may be a bump pad or a bump.

The first core diode structure 131 may include a core N-well region NWc, first core N-doped regions Nc1, and a first core P-doped region Pc1 in the substrate SUB. The first core N-doped regions Nc1 and the first core P-doped region Pc1 may be disposed to be defined and separated apart from each other by the first core isolation regions ISc1. The first core P-doped region Pc1 may be disposed between the first core N-doped regions Nc1. The first core N-doped regions Nc1 may correspond to the N-type electrode of FIG. 3B and the first core P-doped region Pc1 may correspond to the P-type electrode of FIG. 3B.

The first core diode structure 131 may further include first core gate electrodes Gc1 disposed over some of the first core isolation regions ISc1. The first core gate electrodes Gc1 may be dummy gate electrodes. For example, electrical bias may not be applied to the first core gate electrodes Gc1. The first core gate electrodes Gc1 may be electrically floated. Both the first core N-doped regions Nc1 may be commonly and electrically connected to the first voltage node VDD. The first voltage node VDD may be electrically connected to the first power pad V1p. The first core P-doped region Pc1 may be electrically connected to the core element connection pad 135.

The second core diode structure 132 may include a core P-well region PWc, second core P-doped regions Pc2, and a second core N-doped region Nc2 in the substrate SUB. The second core P-doped regions Pc2 and the second core N-doped region Nc2 may be disposed to be separated apart from each other by the second core isolation regions ISc2. The second core N-doped region Nc2 may be disposed between the second core P-doped regions Pc2. The second core diode structure 132 may further include second core gate electrodes Gc2 disposed over some of the second core isolation regions ISc2. The second core gate electrodes Gc2 may be dummy gate electrodes. For example, electrical bias may not be applied to the second core gate electrodes Gc2. The second core gate electrodes Gc2 may be electrically floated. Both the second core P-doped regions Pc2 may be commonly and electrically connected to the second voltage node VSS. The second voltage node VSS may be electrically connected to the second power pad V2p. The second core N-doped region Nc2 may be commonly and electrically connected to the core element connection pad 135. The first core P-doped region Pc1 and the second core N-doped region Nc2 may be electrically connected to each other. Undescribed elements of the core element test structure 130 may be understood with reference to descriptions of elements of the I/O element test structure 110 shown in FIG. 4A.

Specifications of the first and second core diode structures 131 and 132 may be the same as specifications of core transistors disposed in the core region. For example, specifications of well regions, source regions, and drain regions of the first and second core diode structures 131 and 132 and the core transistors may be the same to each other. Thus, electrical characteristics of the core transistors may be measured by using the first and second core diode structures 131 and 132.

The core transistors may operate faster than the I/O transistors under lower voltage and lower current conditions. Therefore, the specifications of the core transistors may be smaller than the specifications of the I/O transistors. For example, volumes of the well regions NWc and PWc and the doping regions Nc1, Nc2, Pc1, and Pc2 of the first and second core diode structures 131 and 132 may be smaller than volumes of the well regions NWi and PWi and the doping regions Ni1, Ni2, Pi1, and Pi2 of the first and second I/O diode structures 111 and 112, respectively. The volume may be at least one of structural values such as depth, length, height, and width. For example, a width Wgi and/or a height Hgi of each of the I/O gate electrodes Gi1 and Gi2 may be greater than a width Wgc and/or a height Hgc of each of the core gate electrodes Gc1 and Gc2. A width Wji and/or a depth Dji of each of the I/O doped regions Ni1, Ni2, Pi1, and Pi2 may be greater than a width Wjc and/or a depth Djc of each of the core doped regions Nc1, Nc2, Pc1, and Pc2. The width Wisi and/or the depth Disi of each of the I/O isolation regions ISi1 and ISi2 may be greater than the width Wisc and/or the depth Disi of each of the core isolation regions ISc1 and ISc2. The depth Dwi of the I/O N-well region NWi and the I/O P-well Pwi may be greater than the depth Dwc of the core N-well region NWc and the core P-well region PWc. Further, the doping concentrations of the well regions NWi and PWi and the doping regions Ni1, Ni2, Pi1, and Pi2 of the first and second I/O diode structures 111 and 112 may be higher than the doping concentrations of the well regions NWc and PWc and the doping regions Nc1, Nc2, Pc1, and Pc2 of the first and second core diode structures 131 and 132.

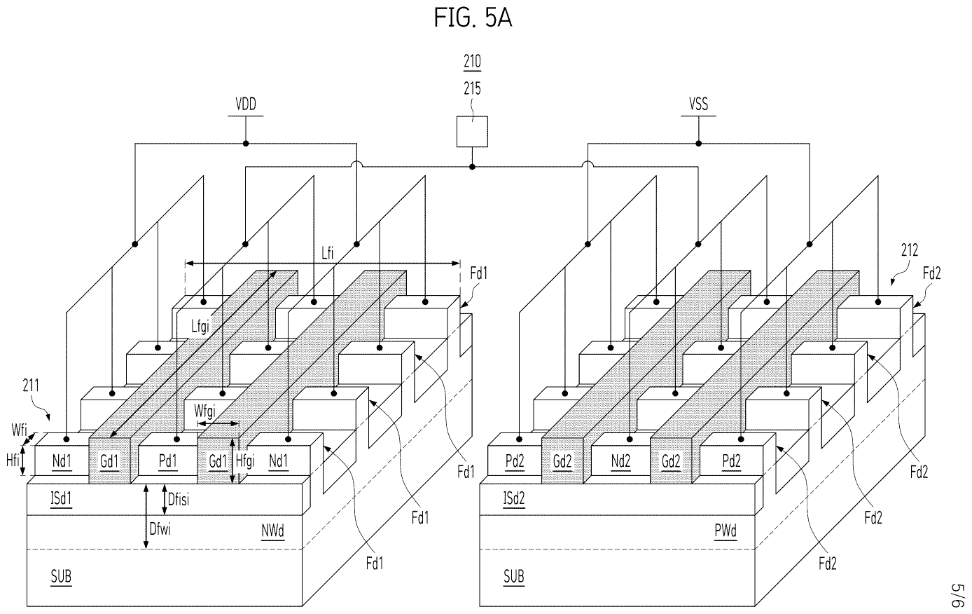

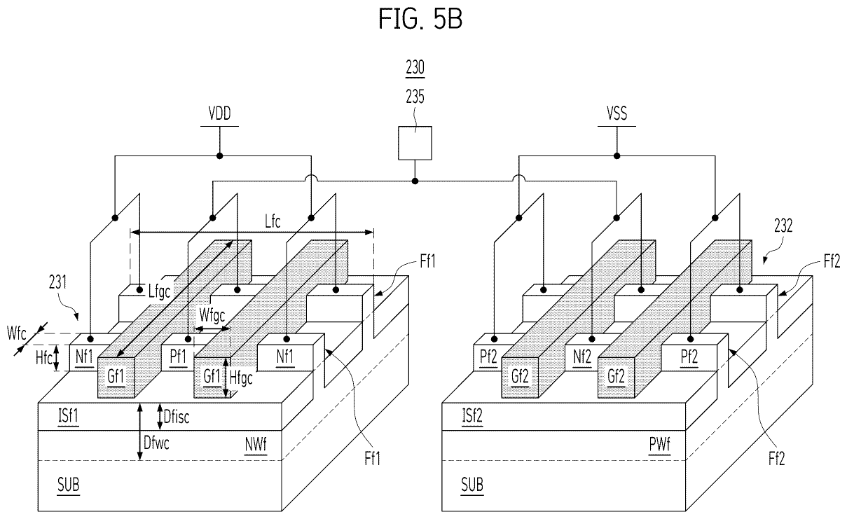

FIG. 5A is a view schematically illustrating an I/O element test structure 210 according to an embodiment of the present disclosure, and FIG. 5B is a view schematically illustrating a core element test structure 230 according to an embodiment of the present disclosure. The I/O element test structure 210 of FIG. 5A and the core element test structure 230 of FIG. 5B may correspond to the I/O element test circuit 10 of FIG. 3A and the core element test circuit 30 of FIG. 3B, respectively.

Referring to FIG. 5A, the I/O element test structure 210 may include a first I/O fin diode structure 211, a second I/O fin diode structure 212, and an I/O element connection pad 215. The first I/O fin diode structure 211 may include a plurality of first I/O fin structures Fd1 protruding from a substrate SUB, and the second I/O fin diode structure 212 may include a plurality of second I/O fin structures Fd2 protruding from the substrate SUB. The first and second I/O fin structures Fd1 and Fd2 may have the same structures. The first I/O fin isolation regions ISd1 may be disposed between the first and second I/O fin structures Fd1 and Fd2. The first I/O fin diode structure 211 may further include a first I/O fin gate electrode Gd1, and the second I/O fin diode structure 212 may further include a second I/O fin gate electrode Gd2. The first I/O fin gate electrode Gd1 may extend to cross the first I/O fin structure Fd1, and the second I/O fin gate electrode Gd2 may extend to cross the second I/O fin structure Fd2. The first and second I/O fin gate electrodes Gd1 and Gd2 may be dummy gate electrodes. For example, electrical bias may not be applied to the first and second I/O fin gate electrodes Gd1 and Gd2. The first and second I/O fin gate electrodes Gd1 and Gd2 may be electrically floated.

The first I/O fin diode structure 211 may include an I/O N-well region NWd and first I/O doped regions Nd1 and Pd1. The I/O N-well region NWd may be formed in lower regions of the first I/O fin structures Fd1. The first I/O N-doped regions Nd1 and the first I/O P-doped regions Pd1 may be formed in upper regions of the first I/O fin structures Fd1.

The first I/O N-doped regions Nd1 of the first I/O fin structures Fd1 may be electrically connected to each other. The first I/O N-doped regions Nd1 may be electrically connected to the first voltage node VDD. The first voltage node VDD may be electrically connected to the first power pad V1p. The first I/O P-doped regions Pd1 of the first I/O fin structures Fd1 may be electrically connected to each other. The first I/O P-doped regions Pd1 of the first I/O fin structures Fd1 may be electrically connected to the I/O element connection pad 215.

The I/O N-well region NWd may include N-type ions doped with an N-type well concentration. The first I/O N-doped regions Nd1 may include N-type ions doped with a first N-doping concentration. The first I/O P-doped regions Pd1 may include P-type ions having a first P-doping concentration. The N-well concentration may be the same as or similar to the first N-doping concentration. In one embodiment, the first N-doping concentration may be higher than the N-well concentration. The first P-doping concentration may be lower than the first N-doping concentration. The first P-doping concentration may be lower than the N-well concentration.

The second I/O fin diode structure 212 may include an I/O P-well region PWd and second I/O doped regions Pd2 and Nd2. The I/O P-well region PWd may be formed in lower regions of the second I/O fin structures Fd2. The second I/O P-doped regions Pd2 and the second I/O N-doped regions Nd2 may be formed in upper regions of the second I/O fin structures Fd2.

The second I/O P-doped regions Pd2 of the second I/O fin structures Fd2 may be electrically connected to each other. The second I/O P-doped regions Pd2 may be electrically connected to the second voltage node VSS. The second voltage node VSS may be electrically connected to the second power pad V2p. The second I/O N-doped regions Nd2 of the second I/O fin structures Fd2 may be electrically connected to each other. The second I/O N-doped regions Nd2 of the second I/O fin structures Fd2 may be electrically connected to the I/O element connection pad 215. The first I/O P-doped regions Pd1 of the first I/O fin structures Fd1 and the second I/O N-doped regions Nd2 of the second I/O fin structures Fd2 may be electrically connected to each other.

The I/O P-well region PWd may include P-type ions doped with a P-well concentration. The second I/O P-doped regions Pd2 may include P-type ions doped with a second P-doping concentration. The second I/O N-doped regions Nd2 may include N-type ions doped with a second N-doping concentration. The P-well concentration may be the same as or similar to the second P-doping concentration. In one embodiment, the second P-doping concentration may be higher than the P-well concentration. The second N-doping concentration may be lower than the second P-doping concentration. The second N-doping concentration may be lower than the P-well concentration.

Referring to FIG. 5B, the core element test structure 230 may include a first core fin diode structure 231, a second core fin diode structure 232, and a core element connection pad 235.

The first core fin diode structure 231 may include a plurality of first core fin structures Ff1 protruding from the substrate SUB, and the second core fin diode structure 232 may include a plurality of second core fin structures Ff2 protruding from the substrate SUB. The plurality of first and second core fin structures Ff1 and Ff2 may have the same structures. First and second core isolation regions ISf1 and ISf2 may be disposed between the first and second core fin structures Ff1 and Ff2. The first core fin diode structure 231 may further include a first core gate electrode Gf1, and the second core fin diode structure 232 may further include a second core gate electrode Gf2. The first core fin gate electrode Gf1 may extend to cross the first core fin structure Ff1, and the second core fin gate electrode Gf2 may extend to cross the second core fin structure Ff2. The first and second core fin gate electrodes Gf1 and Gf2 may be dummy gate electrodes. For example, electrical bias may not be applied to the first and second core fin gate electrodes Gf1 and Gf2. The first and second core fin gate electrodes Gf1 and Gf2 may be electrically floated. The first core fin diode structure 231 may include a core N-well region NWf and first core doping regions Nf1 and Pf1. The core N-well region NWf may be formed in lower regions of the first core fin structures Ff1. The first core N-doped regions Nf1 and the first core P-doped regions Pf1 may be formed in upper regions of the first core fin structures Ff1.

The first core N-doped regions Nf1 of the first core fin structures Ff1 may be electrically connected to each other. The first core N-doped regions Nf1 may be electrically connected to the first voltage node VDD. The first voltage node VDD may be electrically connected to the first power pad V1p. The first core P-doped regions Pf1 of the first core fin structures Ff1 may be electrically connected to each other. The first core P-doped regions Pf1 of the first core fin structures Ff1 may be electrically connected to the core element connection pad 235.

The core N-type region NWf may include N-type ions doped with an N-type concentration. The first core N-doped regions Nf1 may include N-type ions doped at a first N-doping concentration. The first core P-doped regions Pf1 may include P-type ions doped with a first P-doping concentration. The N-well concentration may be the same as or similar to the first N-doping concentration. In one embodiment, the first N-doping concentration may be higher than the N-well concentration. The first P-doping concentration may be lower than the first N-doping concentration. The first P-doping concentration may be lower than the N-well concentration.

The second core fin diode structure 232 may include a core P-well region PWf and second core doping regions Pf2 and Nf2. The core P-well region PWf may be formed in lower regions of the second fin structures Ff2. The second core P-doped regions Pf2 and the second core N-doped regions Nf2 may be formed in upper regions of the second core fin structures Ff2.

The second core P-doped regions Pf2 of the second core fin structures Ff2 may be electrically connected to each other. The second core P-doped regions Pf2 may be electrically connected to the second voltage node VSS. The second voltage node VSS may be electrically connected to the second power pad V2p. The second core N-doped regions Nf2 of the second core fin structures Ff2 may be electrically connected to each other. The second core N-doped regions Nf2 of the second core fin structures Ff2 may be electrically connected to the core element connection pad 235. The first core P-doped regions Pf1 of the first core fin structures Ff1 and the second core N-doped regions Nf2 of the second core fin structures Ff2 may be electrically connected to each other. Undescribed elements of the core element test structure 230 may be understood with reference to descriptions of elements of the I/O element test structure 210 shown in FIG. 5A.

A specification or volume of each of the I/O fin gate electrodes Gd1 and Gd2 may be greater than a specification or volume of each of the core fin gate electrodes Gf1 and Gf2. For example, a width Wfgi, a height Hfgi, and/or a length Lfgi of each of the I/O fin gate electrodes Gd1 and Gd2 may be greater than a width Wfgc, a height Hfgc, and/or a length Lfgc of each of the core fin gate electrodes Gf1 and Gf2.

The specification or volume of each of the I/O fin structures Fd1 and Fd2 may be greater than the specification or volume of each of the core fin structures Ff1 and Ff2. A width Wfi, a height Hfi, and/or a length Lfi of each of the I/O fin structures Fd1 and Fd2 may be greater than a width Wfc, a height Hfc, and/or a length Lfc of each of the core fin structures Ff1 and Ff2.

The specification and/or volume of each of the I/O fin isolation regions ISd1 and ISd2 may be greater than the specification and/or volume of each of the core fin isolation regions ISf1 and ISf2. A depth Dfisi of each of the I/O fin isolation regions ISd1 and ISd2 may be greater than a depth Dfisc of each of the core fin isolation regions ISf1 and ISf2.

The specifications and/or volumes of the I/O NWd and the I/O P-well PWd may be greater than the specifications and/or volumes of the core N-well region NWf and the core P-well region PWf. For example, the depth Dfwi of the I/O NWd and the I/O P-well Pwd may be greater than the depth Dfwc of the core N-well region NWf and the core P-well region PWf.

Further, the doping concentrations of the well regions NWf and PWf and the doping regions Nf1, Nf2, Pf1, and PF2 of the first and second core fin diode structures 231 and 232 may be lower than the doping concentrations of the well regions NWd and PWd and the doping regions Nd1, Nd2, Pd1, and Pd2 of the first and second I/O fin diode structures 211 and 212.

In one embodiment, the volumes of the well regions NWd and PWd and the doping regions Nd1, Nd2, Pd1, and Pd2 of the first and second I/O fin diode structures 211 and 212 and the volumes of the well regions NWe and PWe and PWe and the doping regions Ne1, Ne2, Pe1, and Pe2 of the first and second power fin diode structures 221 and 232 may be the same.

A number of the first and second I/O fin structures Fd1 and Fd1 of the first and second I/O fin diode structures 211 and 212 of the I/O element test structure 210 may be greater than a number of the first and second core fin diode structures Ff1 and Ff2 of the first and second core fin diode structures 231 and 232 of the core element test structure 230.

According to the embodiments of the present disclosure, electrical characteristics of the I/O elements and the core elements can be measured independently and appropriately.

While the present invention has been described with respect to specific embodiments, it will be apparent to those skilled in the art that various changes and modifications may be made without departing from the technical concepts and scope of the disclosure as defined in the following claims. Furthermore, the embodiments may be combined to form additional embodiments.

What is claimed is:

1. A semiconductor device comprising:
a first I/O (input/output) diode having a first I/O first electrode electrically connected to a first voltage node and a first I/O second electrode electrically connected to a first pad;
a second I/O diode having a second I/O first electrode electrically connected to the first pad and a second I/O second electrode electrically connected to a second voltage node;
a first core diode having a first core diode first electrode electrically connected to the first voltage node and a first core diode second electrode electrically connected to a second pad; and
a second core diode having a second core diode first electrode electrically connected to the second pad and a second core diode second electrode electrically connected to the second voltage node,
wherein:
an ion doping concentration of the first I/O first electrode is higher than an ion doping concentration of the second core diode first electrode, and
an ion doping concentration of the first I/O second electrode is higher than an ion doping concentration of the second core diode second electrode.

2. The semiconductor device of claim 1, wherein:
a volume of the first I/O first electrode is greater than a volume of the second core diode first electrode, and
a volume of the first I/O second electrode is greater than a volume of the second core diode second electrode.

3. The semiconductor device of claim 1, wherein:
a doping concentration of a well region of the first I/O diode is higher than a doping concentration of a well region of the first core diode, and
a doping concentration of a well region of the second I/O diode is higher than a doping concentration of a well region of the second core diode.

4. The semiconductor device of claim 3, wherein:
a volume of the well region of the first I/O diode is greater than a volume of the well region of the first core diode, and
a volume of the well region of the second I/O diode is greater than a volume of the well region of the second core diode.

5. The semiconductor device of claim 1, wherein:
the first I/O first electrode and the first I/O second electrode are defined by a first I/O isolation region formed in a substrate,
the second core diode first electrode and the second core diode second electrode are defined by a first core isolation region formed in the substrate, and
a volume of the first I/O isolation region is greater than a volume of the first core isolation region.

6. The semiconductor device of claim 1, wherein:
the first I/O diode further includes a first I/O gate electrode disposed over a substrate between the first I/O first electrode and the first I/O second electrode,
the first core diode further includes a first core gate electrode disposed over the substrate between the first I/O first electrode and the first I/O second electrode, and
a volume of the first I/O gate electrode is greater than a volume of the first core gate electrode.

7. The semiconductor device of claim 1, wherein:
the first I/O diode includes a plurality of first I/O fin structures,
the first core diode includes a plurality of first core fin structures, and
a number of the first I/O fin structures is greater than a number of the first core fin structures.

8. The semiconductor device of claim 7, wherein:
the second I/O diode includes a plurality of second I/O fin structures,
the second core diode includes a plurality of second core fin structures, and
a number of the second I/O fin structures is greater than a number of the second core fin structures.

9. The semiconductor device of claim 8,
wherein the number of the first I/O fin structures is equal to the number of the second I/O fin structures.

10. The semiconductor device of claim 8,
wherein the number of the first core fin structures is equal to the number of the second core fin structures.

11. The semiconductor device of claim 8,
wherein a volume of each of the plurality of second I/O fin structures is greater than a volume of each of the plurality of second core fin structures.

12. The semiconductor device of claim 7,
wherein a volume of each of the plurality of first I/O fin structures of the first I/O diode is larger than a volume of each of the plurality of first core fin structures of the first core I/O diode.

13. The semiconductor device of claim 7, wherein:
a number of the plurality of first I/O fin regions is greater than a number of the plurality of first core fin regions, and
a number of the plurality of second I/O fin regions is greater than a number of the plurality of second core fin regions.

14. A semiconductor device comprising:
a first diode structure electrically connected to a first pad; and
a second diode structure electrically connected to a second pad,
wherein the first diode structure includes:
a plurality of first fin structures;
first well regions disposed in lower regions of the plurality of first fin structures; and
first N-doped regions and second P-doped regions disposed in upper regions of the plurality of first fin structures,
wherein the second diode structure includes:
a plurality of second fin structures;
second well regions disposed in lower regions of the plurality of second fin structures; and
second N-doped regions and second P-doped regions disposed in upper regions of the plurality of second fin structures, and
wherein a number of the plurality of first fin structures is greater than a number of the plurality of second fin structures.

15. The semiconductor device of claim 14,
wherein a doping concentration of each of the first well regions is higher than a doping concentration of each of the second well regions.

16. The semiconductor device of claim 14,
wherein an N-doping concentration of the first N-doped regions is higher than an N-doping concentration of the second N-doped regions.

17. The semiconductor device of claim 14,
wherein a P-doping concentration of the first P-doped regions is higher than a P-doping concentration of the second P-doped regions.

18. The semiconductor device of claim 14,
wherein a volume of each of the plurality of first fin structures is greater than a volume of each of the plurality of second fin structures.

19. The semiconductor device of claim 14, wherein:
the first diode structure includes a first fin gate electrode crossing the plurality of first fin structures,
the second diode structure includes a second fin gate electrode crossing the plurality of second fin structures, and
a volume of the first fin gate electrode is greater than a volume of the second fin gate electrode.

20. A semiconductor device comprising:
a first I/O diode having a first I/O first electrode electrically connected to a power voltage node and a first I/O second electrode electrically connected to an I/O pad;
a second I/O diode having a second I/O first electrode electrically connected to the I/O pad and a second I/O second electrode electrically connected to a ground voltage node;
a first core diode having a first core diode first electrode electrically connected to the power voltage node and a first core diode second electrode electrically connected to a core pad; and
a second core diode having a second core diode first electrode electrically connected to the core pad and a second core diode second electrode electrically connected to the ground voltage node,
wherein:
a doping concentration of each of doping regions of the first and second I/O diodes is higher than a doping concentration of each of doping regions of the first and second core diodes, and
a volume of each of the doping regions of the first and second I/O diodes is greater than a volume of each of the doping regions of the first and second core diodes.
